(19) United States
(12) Patent Application Publication
(10) Pub. No.: US 2009/0035463 A1
(43) Pub. Date: Feb. 5, 2009

(54) THERMAL PROCESSING SYSTEM AND METHOD FOR FORMING AN OXIDE LAYER ON SUBSTRATES

(75) Inventor: Anthony Dip, Cedar Creek, TX (US)

Correspondence Address: WOOD, HERRON & EVANS, LLP (TOKYO ELECTRON), 2700 CAREW TOWER, 441 VINE STREET, CINCINNATI, OH, 45202, US

(73) Assignee: TOKYO ELECTRON LIMITED, Tokyo (JP)

(21) Appl. No.: 11/833,754

(22) Filed: Aug. 3, 2007

(51) Int. Cl. C23C 16/452; C23C 16/455

(52) U.S. Cl. 427/255.26; 118/720; 427/255.28; 427/255.29

(57) ABSTRACT

Thermal processing system and method for forming an oxide layer on substrates. The thermal processing system has a gas injector with first and second fluid lumens confining first and second process gases, such an molecular hydrogen and molecular oxygen, from each other and another fluid lumen that receives the process gases from the first and second fluid lumens. The first and second process gases combine and react in this fluid lumen to form a reaction product. The reaction product is injected from this fluid lumen into a process chamber of the thermal processing system, where substrates are exposed to the reaction product resulting in formation of an oxide layer.

### FIELD OF THE INVENTION

This invention relates to the field of semiconductor processing, and, more particularly, to thermal processing systems with improved injection of process gases and methods for injecting process gases into a thermal processing system to form an oxide layer on substrates held in the system.

### BACKGROUND OF THE INVENTION

Thermal processing systems are commonly used to perform a variety of semiconductor fabrication processes including, but not limited to, oxidation, diffusion, annealing, and chemical vapor deposition (CVD). Most conventional thermal processing systems employ a process chamber that is oriented either horizontally or vertically. Vertical thermal processing systems are recognized to generate fewer particles during processing, which reduces substrate contamination, are readily automated, and require less floor space because of their relatively small footprint.

Low pressure radical oxidation (LPRO) is an established process used in large batch thermal processing systems featuring hot wall reaction chambers. LPRO primarily consists of injecting molecular hydrogen and molecular oxygen from separate gas injectors at an elevated temperature exceeding 800° C. and a low pressure less than 1 Torr into the process chamber. These process gases are typically injected near the crown or top of the process chamber above a stack of substrates. Molecular hydrogen is injected into the reaction chamber from one injector and molecular oxygen is injected into the reaction chamber from a separate injector. Injection at a point remote from the substrates is necessary to permit the process gases enough time to intermix and partially react to form a quasi-stable population of highly-reactive atomic oxygen. The process gases react in the same volume of the reaction chamber in which the substrates reside and, therefore, in close proximity with the substrates.

Under nominal LPRO processing conditions, the molecular hydrogen and molecular oxygen react to form various reaction products, including water, OH groups, atomic hydrogen, and atomic oxygen, in relative abundances contingent upon the reaction conditions. Of these reaction products, atomic oxygen is the most directly related to the oxidation process transpiring at the substrates. At higher gas pressures than those normally used in LPRO, the reaction between the molecular hydrogen and molecular oxygen proceeds too quickly, which forms only water and little usable atomic oxygen. The desired gas phase reaction product of LPRO is a high concentration of uniformly distributed atomic oxygen in order to promote a short oxidation time and uniform film formation on the substrates. The short oxidation time increases the process throughput, which is beneficial. Water, which is not a desired reaction product, has a minimal effect on the oxidation process at low pressures despite the high substrate temperatures.

When processing a large number of substrates by LPRO in a thermal processing system, careful control of the atomic oxygen density in the gas phase is needed. Because LPRO is executed with a low pressure in the reaction chamber, consumption of the atomic oxygen species leads to depletion effects. As mentioned above, the molecular hydrogen and molecular oxygen process gases are injected at one end of the batch tube and the reaction chamber is exhausted at the opposite end of the batch tube. As the process gases and reaction products travel through the reaction chamber, the atomic oxygen species is consumed by reaction with the substrates producing the oxide. Because the oxidation rate is approximately proportional to the square of the concentration of the atomic oxygen species in the gas phase, consumption of the atomic oxygen from the gas phase leads to a drop in the oxidation rate with increasing distance from the injection points of molecular hydrogen and molecular oxygen.

One conventional solution that attempts to compensate for the depletion of atomic oxygen is to supply an over-abundance of molecular hydrogen to the process chamber through a multiplicity of side injectors each coupled by an independent gas line with a mass flow controlled source. As a result, multiple mass flow controllers equal in number to the number of gas injectors are required for supplying one of the process gases, namely the molecular hydrogen. Furthermore, adjusting the injection of molecular hydrogen from these multiple side injectors, which is a manual adjustment dependent upon the load pattern for the substrates and the type of substrate, to optimize the LPRO process may be difficult.

There is thus a need for a thermal processing system and method with improved process gas delivery that compensates for the changing population of atomic oxygen in the gas phase so as to overcome these and other deficiencies of conventional thermal processing systems.

### SUMMARY OF THE INVENTION

Thermal processing systems and methods are provided for processing substrates using a reaction product generated from first and second process gases. In one embodiment, the thermal processing system comprises a tubular member defining a process chamber in which the substrates are held for processing and a gas injector having a manifold body disposed in the process chamber. The manifold body may include a first tubular conduit, a first lumen defined inside the first tubular conduit, a plurality of injection outlets coupling the first lumen in fluid communication with the process chamber, a second lumen that confines a first process gas, and a third lumen that confines a second process gas inside the manifold body and segregated from the first process gas. The second and third lumens may be coupled in fluid communication with the first lumen. The first tubular conduit is configured to combine the first and second process gases to promote a chemical reaction within the first lumen that produces the reaction product, which is subsequently injected through the injection outlets into the process chamber.

In one embodiment, the method comprises combining the first and second process gases within a tubular conduit inside the process chamber to promote a chemical reaction producing the reaction product. The method further comprises exposing a plurality of substrates supported inside the process chamber to the reaction product injected from injection outlets of the tubular conduit into the process chamber.

### BRIEF DESCRIPTION OF THE DRAWINGS

The accompanying drawings, which are incorporated in and constitute a part of this specification, illustrate embodiments of the invention and, together with a general description of the invention given above, and the detailed description given below, serve to explain the invention.

FIG. 1 is a cross sectional front view of a thermal processing system that includes a gas injector in accordance with an embodiment of the invention.

FIG. 1A is an isometric view of the liner of FIG. 1;

FIG. 2 is an isometric view of the gas injector of FIG. 1;

FIG. 3 is a cross-sectional view taken generally along line 3-3 of FIG. 2;

FIG. 4 is a cross-sectional view taken generally along line 4-4 of FIG. 3;

FIGS. 5A-5G are cross-section views illustrating an embodiment of a procedure for assembling the gas injector shown in FIGS. 2-4; and

FIG. 6 is a graphical representation showing the mole concentration of atomic oxygen and the predicted oxidation uniformity as a function of the total gas flow in a thermal processing system equipped with a gas injector of an embodiment of the invention.

### DETAILED DESCRIPTION

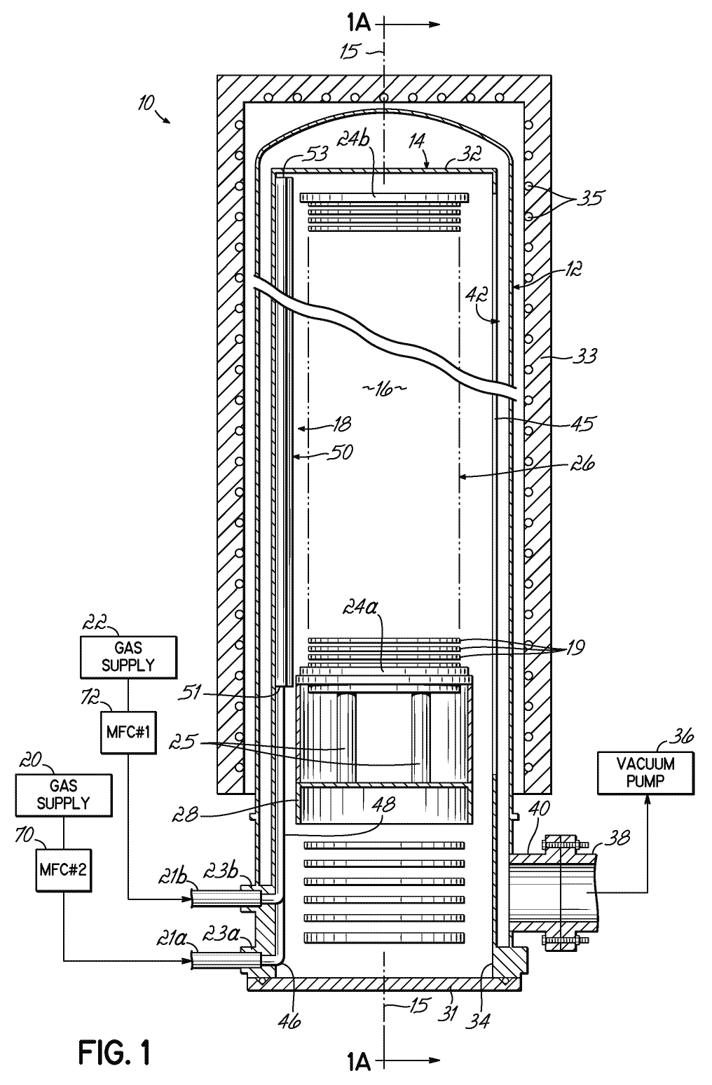

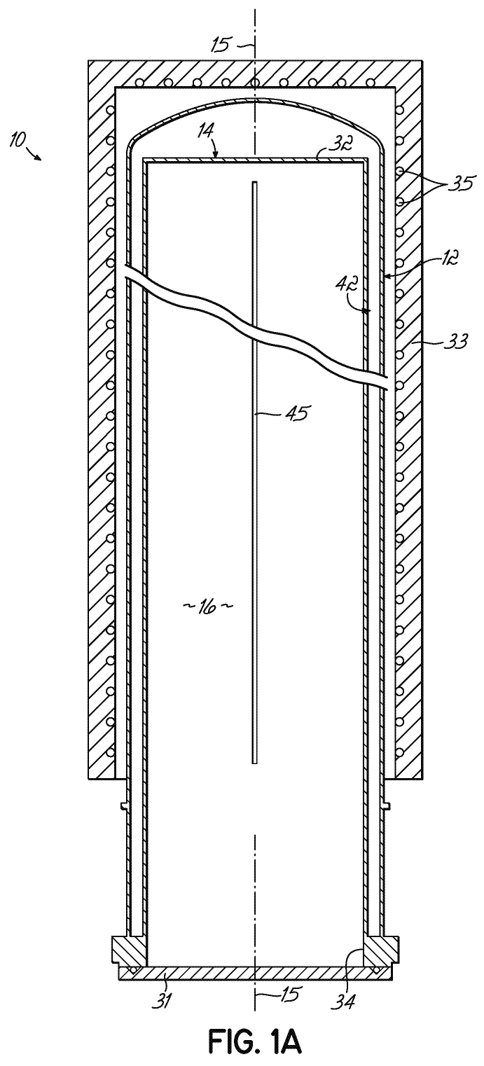

With reference to FIGS. 1 and 1A, a process tool in the form of a thermal processing system 10 comprises an outer vessel or tube 12 and an inner batch tube or liner 14 disposed radially inside the outer tube 12. The liner 14 surrounds a process chamber 16 that is adapted to receive a batch or stack of workpieces or substrates 19, such as silicon wafers of a given diameter. The dimensions of the liner 14, and thus the size of the thermal processing system 10, may be scaled to accommodate substrates 19 of different sizes. The liner 14, which is generally shaped like a right circular cylinder substantially centered about an azimuthal axis 15, may be composed of any high temperature material, such as quartz, silicon carbide, or other suitable ceramic material, and is removable for cleaning to remove accumulated deposits that are an artifact of substrate processing.

The thermal processing system 10 includes a gas injector 18 that receives a metered stream or flow of two different reactants, which may have the representative form of process gases that are typically electronics grade in purity. A delivery line 21a communicates a flow of the first process gas from the first process gas supply 20 and through a fluid feedthrough 23a penetrating the outer tube 12 and liner 14 to a delivery section 46 of the gas injector 18. Another delivery line 21b communicates a flow of the second process gas from the second process gas supply 22 and through a fluid feedthrough 23b penetrating the outer tube 12 and liner 14 to a delivery section 48 of the gas injector 18. The delivery lines 21a, 21b, which are commonly made of a stainless steel, transition in the fluid feedthroughs 23a, 23b to communicate with the gas injector 18, which is commonly formed from a ceramic like quartz. In this manner, the process gases are transferred from the environment surrounding the thermal processing system 10 to the gas injector 18.

A carrier in the form of a boat 26, which may be composed of a high-temperature material such as quartz, is disposed inside the thermal processing system 10. The boat 26 is supported on a pedestal 28, which is lifted and lowered by a boat elevator (not shown) for exchanging substrates 19. The boat 26 includes a plurality of substrate holders defining vertically spaced slots for the substrates 19, which are supported about their peripheral edges. The substrate holders of the boat 26 are arranged in a vertically spaced relationship with a plurality of rods 25. The rods 25, which are mounted to the pedestal 28, extend between opposite end plates 24a,b and are arranged relative to each other to provide an access path to each of the slots. Substrates 19 are held by the boat 26 in a spaced arrangement such that process gases and reaction product(s) readily passes through a gap, G, defined between each pair of adjacent substrates 19. Unprocessed substrates 19 may be loaded into boat 26 and processed substrates 19 may be unloaded from the boat 26 by an end effector on an articulated arm of a wafer-handling robot (not shown).

The liner 14, which peripherally bounds the process chamber 16, has a closed end 32 and an open end 34 spaced along the azimuthal axis 15 from the closed end 32. The open end 34 has a sealing engagement with a base plate 31 to form the process chamber 16, which completely encloses the substrates 19 during thermal processing. The boat 26 and the substrates 19 held in a stack by the boat 26 are disposed inside the liner 14 generally between the closed and open ends 32, 34 of the liner 14. The pedestal 28 may be configured to rotate about the azimuthal axis 15 relative to the liner 14 so that the substrates 19 and boat 26 can be rotated during processing. The outer tube 12 and liner 14 may be arranged concentric with the azimuthal axis 15, as well as concentric with the rotating substrates 19 and boat 26.

A heat source 33, which is positioned outside of the outer tube 12, includes heating elements 35 used to elevate the temperature of the outer tube 12 and liner 14 by heat transfer so that the process chamber 16 is surrounded by a hot wall when the substrates 19 are exposed to the process gases and reaction product(s). The heat source 33 also operates to heat the substrates 19 and the gases in the gas injector 18. The heat source 33 may be divided into a plurality of heating zones each having an independent power source/temperature controller for controlling the corresponding zone temperature. Temperature detectors (not shown), such as thermocouples or resistance temperature devices, are stationed along the height of the liner 14 and provide temperature information to the different power sources/controller for use in regulating the temperature of the liner 14 in the different heating zones. The power source/temperature controller may employ, for example, a proportional integral derivative (PID) algorithm based on feedback from the temperature detectors to determine the power applied to each zone of the heat source 33 based upon the discrepancy between each set of monitored and target temperatures. Typically, the zone temperatures of the heat source 33 are regulated to provide an approximately flat or isothermal temperature profile for the liner 14 at a target temperature characteristic of the process, which is typically in the range of 200° C. to 1200° C. and, more typically, in the range of 250° C. to 800° C.

The process chamber 16 is evacuated through an annular pumping space 42, which is defined between the outer tube 12 and the liner 14. As best shown in FIG. 1A, the process chamber 16 and the annular pumping space 42 are coupled in fluid communication by a narrow longitudinal slit 45 extending through the liner 14. A vacuum port 40 penetrates the outer tube 12 near the open end 34 of the liner 14 and a foreline 38 couples a suitable vacuum pump 36 with the vacuum port 40. The annular pumping space 42 is actively pumped by the vacuum pump 36 through the vacuum port 40. During operation of thermal processing system 10, the evacuation of the process chamber 16 is continuous, as is the injection of the process gases and reaction product(s) from the gas injector 18 into the process chamber 16. The sub-atmospheric pressure within the process chamber 16 can be adjusted and controlled by altering the pumping speed of gases through foreline 38 and vacuum port 40 and by selection of the vacuum pump 36 and the rate at which process gases and reaction product(s) are introduced from the gas injector 18 into the process chamber 16.

The gas injector 18, which is stationed primarily inside the process chamber 16, has a first tubular delivery section 46 that enters the liner 14 at a fluid entrance point via fluid feedthrough 23a and then bends at a near right angle to rise vertically near the inner wall of the liner 14. The gas injector 18 further includes a second tubular delivery section 48 that enters the liner 14 at a fluid entrance point via fluid feedthrough 23b and then bends at a near right angle to also rise vertically near the inner wall of the liner 14 and proximate to the first tubular delivery section 46.

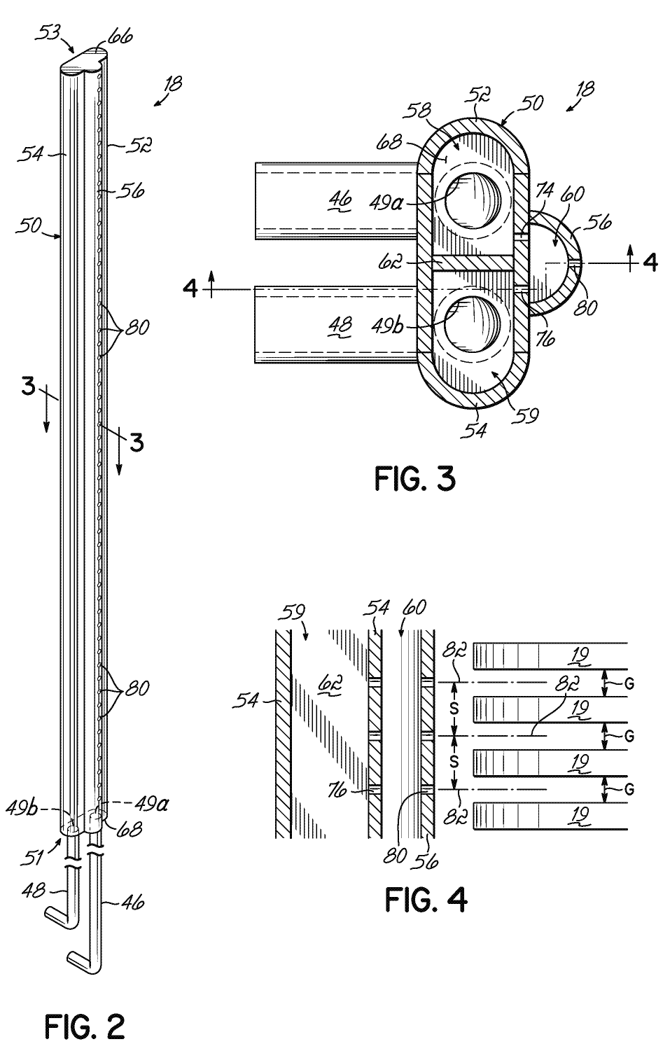

The delivery sections 46, 48 intersect and join with a manifold body 50 of the gas injector 18 that is positioned radially relative to azimuthal axis 15 between the liner 14 and the boat 26. The intersection of the delivery section 46 with the manifold body 50 defines an inlet 49a (FIG. 2) for one of the process gases originating from gas supply 20. The intersection of the delivery section 48 with the manifold body 50 defines another inlet 49b (FIG. 2) for one of the process gases originating from gas supply 20. In this manner, the process gases are communicated from the delivery sections 46, 48 to the manifold body 50. The inlets 49a, 49b penetrate through a cap 68 located at one end 51 of the manifold body 50. The manifold body 50 defines a rise that extends vertically from the cap 68 to another cap 66 located at end 53, which is proximate to the closed end 32 of the liner 14.

The longitudinal slit 45 is located angularly in the liner 14 and about the azimuthal axis 15 approximately diametrically opposite to the location of the manifold body 50 of the gas injector 18 and has an axial extent similar to the manifold body 50. In other words, the angular arc between the longitudinal slit 45 and the manifold body 50 is approximately 180°. As a result, process gas cross-flow is promoted by the gas injector 18, which inject the process gas, and the longitudinal slit 45, which provides the outlet for the unreacted process gas and volatile reaction products to the annular pumping space 42. The dimensions of the longitudinal slit 45 may be selected to provide a targeted cross-flow of process gas across the substrates 19 in the boat 26.

With reference to FIGS. 2-4 in which like reference numerals refer to like features in FIG. 1, the manifold body 50 of the gas injector 18 includes a plurality of tubular conduits 52, 54, 56 each bounding a sub-chamber in the form of a respective fluid lumen 58, 59, 60. In the representative embodiment, a partition 62 divides a continuous oval shaped sidewall to define tubular conduits 52, 54, although the invention is not so limited. The tubular conduits 52, 54, 56 are sealed at opposite ends by caps 66, 68. Cap 68 is penetrated by the inlets 49a, 49b for establishing fluid communication with the respective delivery sections 46, 48. The fluid lumen 58 of tubular conduit 52 is coupled by inlet 49a with delivery section 46 and, similarly, the fluid lumen 59 of tubular conduit 54 is coupled by inlet 49b with delivery section 48. The fluid lumens 58, 59 are mutually isolated from each other so that the process gases cannot combine inside either of the fluid lumens 58, 59, but are instead restricted to combine within the fluid lumen 60 of tubular conduit 56.

Mass flow controllers 70, 72 (FIG. 1) are respectively stationed in the delivery lines 21a, 21b between the gas supplies 20, 22 and the fluid feedthroughs 23a, 23b. Each of the mass flow controllers 70, 72, which have a construction understood by a person having ordinary skill in the art, may be provided with feedback loop control to maintain a selected pressure setting for the two different process gases flowing in the respective delivery lines 21a, 21b and delivered to the tubular conduits 52, 54. The proximity of the manifold body 50 of the gas injector 18 to the heated liner 14 rapidly heats the process gases flowing in delivery sections 46, 48 and tubular conduits 52, 54 significantly above the entry temperature at the fluid feedthroughs 23a, 23b.

Gas passages 74 penetrate the sidewall of tubular conduit 52 along the length of the manifold body 50 of gas injector 18. The gas passages 74 couple the fluid lumen 58 inside tubular conduit 52 in fluid communication with the fluid lumen 60 inside tubular conduit 56. The gas passages 74 define discrete pathways for communicating the process gas originating from gas supply 20 from tubular conduit 52 to tubular conduit 56. Similarly, the sidewall of tubular conduit 54 is pierced along its length by gas passages 76, which couple the fluid lumen 59 inside tubular conduit 54 in fluid communication with the fluid lumen 60 inside tubular conduit 56. The gas passages 76 communicate the process gas originating from gas supply 22 from tubular conduit 54 to tubular conduit 56. This transfer is accomplished independent of the different process gas originating from gas supply 20 and communicated from tubular conduit 52 to tubular conduit 56 by gas passages 74.

Injection outlets 80, which pierce the sidewall of the gas injector 18, are distributed along the length of the tubular conduit 56. In the representative embodiment, the centers of the injection outlets 80 are substantially aligned in a row or line extending along the length of the tubular conduit 56. Similarly, the centers of gas passages 74 and gas passages 76 may each be substantially aligned in respective first and second rows along the respective lengths of the tubular conduits 52, 54 that are oriented substantially parallel with the rows of the injection outlets 80. The process gases and any reaction product(s) formed from the combination and reaction of the process gases in the fluid lumen 60 are communicated by the injection outlets 80 to the process chamber 16.

Each of the injection outlets 80 is symmetrical about a central axis 82, which is oriented generally radially relative toward the azimuthal axis 15 (FIG. 1). Although the injection outlets 80 are shown with a round cross section of uniform diameter, other tubular geometrical shapes may be used as understood by a person having ordinary skill in the art. The injection outlets 80 have a pitch or center-to-center distance, S, measured between the corresponding central axes 82 of adjacent outlets 80. The pitch of at least a majority, if not all, of the injection outlets 80 may be selected such that the central axis 82 is aligned with a plane equidistant from and parallel with a nearest pair of adjacent or nearest-neighbor substrates 19 held in the boat 26. Consequently, the injection outlets 80 and the substrates 19 may be arranged with substantially identical pitches. The process gases and any reaction product(s) formed from the combination and reaction of the process gases in the fluid lumen 60 are injected into these gaps, G, between adjacent pairs of substrates 19.

In use and with reference to FIGS. 1, 1A, 2, 3, and 4, a process run is initiated with the liner 14 held at an idle temperature elevated significantly above room temperature. The substrates 19 are loaded into the boat 26 and the temperature of the liner 14 is elevated to the target process temperature. The fluid lumen 58 of tubular conduit 52 receives a regulated stream of one of the process gases from gas supply 20 that has been metered by mass flow controller 70. The fluid lumen 59 of tubular conduit 54 receives a regulated stream of the other of the process gases from gas supply 22 that has been metered by mass flow controller 72. The process gases are directed from the gas supplies 20, 22 at respective controlled flow rates established by the setting of the respective one of the mass flow controllers 70, 72. The individual process gases, which are segregated from each other while inside fluid lumens 58, 59 so that any mutual chemical reaction between the process gases is averted, fill the fluid lumens 58, 59. Heat transferred from the liner 14 to the tubular conduits 54, 56 heats the process gases over the vertical rise of the gas injector 18 toward the closed end 32 of liner 14.

The process gases are individually directed from the fluid lumens 58, 59 through the respective gas passages 74, 76 into the fluid lumen 60 of tubular conduit 56 along the length of the manifold body 50 of the gas injector 18. The fluid lumens 58, 59 are not in direct fluid communication with each other and the positive flows of the pressurized process gases from the fluid lumens 58, 59 into fluid lumen 60 prevent any backflow of the process gases that would result in the different process gases combining and reacting within either of the fluid lumens 58, 59. The process gases combine and react in the fluid lumen 60 of tubular conduit 56, which is also heated by heat transfer from the liner 14, to form one or more reaction products. The reaction product(s) and process gases are subsequently injected through injection outlets 80 spaced along the length of the manifold body 50 into process chamber 16. During a process run, the process chamber 16 contains a sub-atmospheric pressure of the process gases and one or more reaction products delivered from the gas injector 18. The residence time of the process gas and reaction product(s) in the process chamber 16 is sufficient to promote a chemical reaction that deposits or grows a layer of an oxide on each of the substrates 19.

Volatile reaction products and any unreacted process gases are evacuated from the process chamber 16 inside the liner 14 through the longitudinal slit 45, into the annular pumping space 42, and ultimately to the vacuum port 40. After a given dwell time at the process temperature sufficient to achieve the desired process treating substrates 19, the process gas flow is discontinued, the liner 14 is cooled back to an idle temperature, and the processed substrates 19 are unloaded from the boat 26. Unprocessed substrates 19 are loaded into the boat 26 and another process run is initiated.

In one embodiment, the first process gas supplied from process gas supply 20 may be a hydrogen-containing process gas like H₂ and the second reactant supplied from a second process gas supply 22 may be an oxygen-containing process gas like O₂. In this embodiment, the hydrogen-containing and oxygen-containing process gases, after being heated in tubular conduits 52, 54, chemically react upon being combined in tubular conduit 56 to generate atomic oxygen that is highly chemically reactive with the substrates 19 and, in particular, with silicon substrates 19. In effect, the fluid lumen 60 of tubular conduit 56 defines a combustion cavity in which the individual process gases are permitted to combine and ignite (i.e., combust) to form atomic oxygen. The atomic oxygen forms an oxide layer of at least one surface of each of the substrates 19.

The cross-sectional area of the fluid lumen 60 and the dimensions of the injection outlets 80 may be dimensioned to regulate the reaction kinetics of the chemical reaction of the process gases so that a desired reaction product is generated. For example, the cross-sectional area of the fluid lumen 60 and the dimensions of the injection outlets 80 may be tailored to adjust the pressure and residence time of the process gases to adjust the resultant reaction product. Of course, process gas temperature while resident in fluid lumen 60 plays a role in the reaction kinetics as well. As a more specific example, the cross-sectional area of the fluid lumen 60 and the dimensions of the injection outlets 80 may be tailored to adjust the pressure of hydrogen-containing and oxygen-containing process gases within the fluid lumen 60 so that the production of atomic oxygen from their chemical reaction is optimized. The gas pressure within fluid lumen 60 may be on the order of about 1 Torr to about 10 Torr to optimize the formation of atomic oxygen for injection from the injection outlets 80 into the process chamber 16.

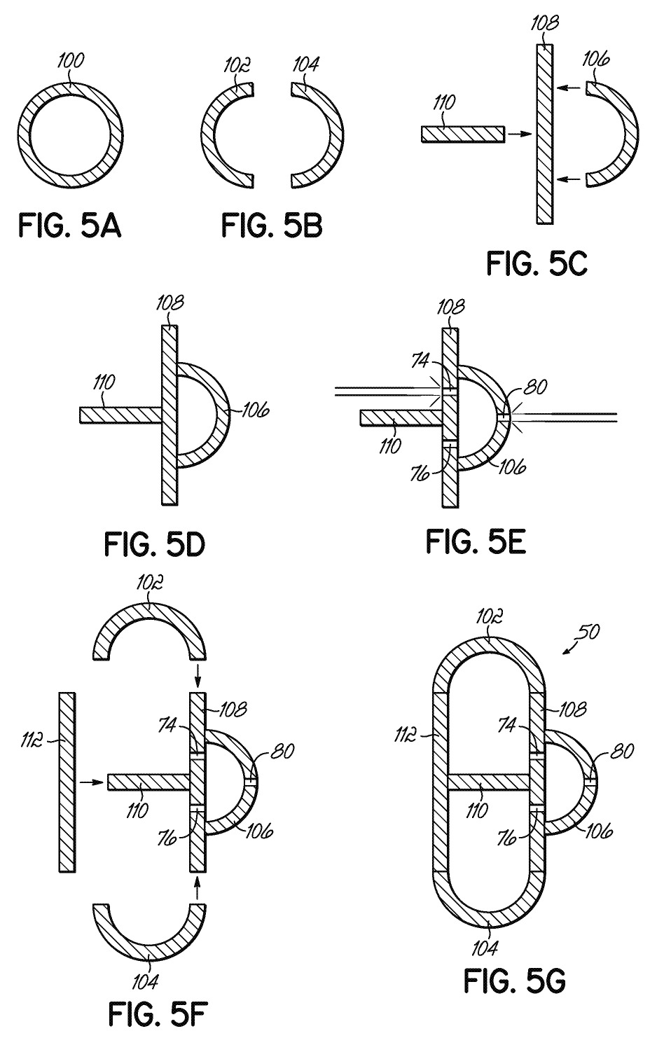

With reference to FIGS. 5A-5G, a representative method for making the manifold body 50 of gas injector 18 is described. As shown in FIGS. 5A and 5B, a circular tube 100 of an appropriate length is split lengthwise and diametrically into two semicircular halves 102, 104. As shown in FIGS. 5C and 5D, a semicircular half 106 of another circular tube (not shown), which is similar in shape to semicircular halves 102, 104, is joined with the concave face oriented toward one side of a flat plate 108. Another flat plate 110 is joined at an angle to the flat plate 108. In the representative embodiment, the plates 108, 110 are joined with an approximately perpendicular arrangement. As shown in FIG. 5E, gas passages 74, 76 are defined in the flat plate 108 and injection outlets 80 are defined in the semicircular tube half 106. The gas passages 74, 76 and injection outlets 80 may be laser cut in the material forming the flat plate 110 and semicircular half 106.

As shown in FIGS. 5F and 5G, another flat plate 112 and the semicircular halves 102, 104 are assembled with the partially-assembled structure of FIG. 5E to form the manifold body 50 of gas injector 18. The semicircular halves 102, 104 are oriented so that the respective concavities face toward the flat plate 110. In subsequent manufacturing steps (not shown), the caps 66, 68 are joined to the manifold body 50, the inlets 49a, 49b are defined in cap 68, and delivery sections 46, 48 are joined with the inlets 49a, 49b. A conventional hydrogen torch may be used to perform the joining processes for the components by forming continuous, pinhole-free welds across the various joints of the manifold body 50.

The utilization of two separate fluid lumens 58, 59 in gas injector 18 for the uncombined process gases reduces the number of mass flow controllers required from a number exceeding two in conventional gas injectors to only two for gas injector 18. In the representative embodiment, mass flow controller 70 regulates the mass flow rate for transporting one of the process gases (i.e., an oxidizing process gas like an oxygen-containing process gas) to fluid lumen 58 inside tubular conduit 52 and mass flow controller 72 independently regulates the mass flow rate for transporting the other of the process gases (i.e., a reducing process gas like a hydrogen-containing process gas) to fluid lumen 59 inside tubular conduit 54. The gas injector 18 is independent structurally from tube 12 and liner 14 and is not welded or otherwise joined with either structural feature, which reduces the expense and complexity to manufacture gas injector 18.

The manifold body 50 contains three sub-chambers consisting of fluid lumen 58 that confines the first process gas (e.g., molecular oxygen comprising the fuel), fluid lumen 59 that confines the second process gas (e.g., molecular hydrogen comprising the oxidizer), and fluid lumen 60 that permits the first and second process gases to be combined for chemical reaction in the form combustion (i.e., ignition). By controlling the volume of fluid lumen 60, along with the method of injection and ejection of the process gases from fluid lumen 60 into the process chamber 16, a localized source of atomic oxygen is supplied from each of the injection outlets 80 to at least the nearest substrate 19 in the boat 26. The atomic oxygen reacts with the constituent material of the substrates 19 to form an oxide layer on at least one surface of each of the substrates 19.

The overall system configuration of thermal processing system 10 promotes cross flow from the injection outlets 80 of the gas injector 18 to the longitudinal slit 45 extending through the liner 14. Conventional system designs inject the process gases near the top of the process chamber and evacuate the gases near the bottom of the process chamber. However, the process gases and reaction product(s) are injected from the manifold body 50 of gas injector 18 at uniform points defined by the line of injection outlets 80 along side of the stack of substrates 19 in boat 26 and are evacuated at the opposite side of the process chamber 16.

By accelerating the combustion process at elevated pressures and ejecting the gas immediately into a low-pressure environment inside the process chamber 16, the gas injector 18 can supply a uniform and high concentration of atomic oxygen to all substrates 19 with relative immunity to substrate loading conditions. Furthermore, the apparatus and method of injection dramatically increases the levels of atomic oxygen at temperatures below conventional LPRO temperatures and with acceptable spatial uniformity. The depletion of the atomic oxygen is reduced, in comparison with conventional thermal processing systems, across the load represented by the substrates 19 in the boat 26 because each individual substrate 19 has a dedicated local source of atomic oxygen from an adjacent injection outlet 80. The primary flow of reactive gases occurs generally parallel to the surface of the substrate 19. High concentrations of atomic oxygen can be generated at relatively low temperatures (about 800° C. or less) with acceptable spatial uniformity throughout the entire process chamber 16.

Because the density of atomic oxygen across the process chamber 16 is uniform, a flat temperature profile can be applied for the heating zones of the liner 14 such that little or no temperature tilting or skewing is necessitated along the length of liner 14. The thermal processing system 10 lacks the multiple molecular hydrogen injectors that may be required in conventional thermal processing systems, which eliminates the time consuming process for adjusting the operation of these injectors to optimize the system performance. The gas injector 18 may require lower total process gas flows, in comparison with conventional gas injectors, which may reduce equipment costs by simplifying the requirements for foreline 38 and vacuum pump 36.

Further details and embodiments of the invention will be described in the following example and contrasted with a comparative example representative of the prior art.

### EXAMPLE AND COMPARATIVE EXAMPLE

Fluid flow inside a representative thermal processing system similar to thermal processing system 10 (FIG. 1) was simulated by computational modeling using FLUENT computational fluid dynamics (CFD) software executing on a 64-bit dual CPU workstation. The CFD modeling relies on a numerical computation using a finite element code embodied in the CFD software, in which a volume inside the thermal processing system is modeled with discrete volume elements or cells. The CFD software FLUENT is commercially available from Fluent, Inc. (Centerra Resource Park, 10 Cavendish Court, Lebanon, N.H.). Other CFD modeling packages are well known in the art.

The system modeled by way of the CFD computation was a 200 mm cross flow Alpha 8SE thermal processing tool, which is commercially available from Tokyo Electron Limited, configured with a gas injector similar to the gas injector 18 (FIGS. 1-4). The processing space was resolved into approximately 2.5 million cells for the high-resolution simulation. The processing space was loaded with wafers at a 5.2 mm pitch (e.g., pitch S in FIG. 4). Hydrogen was used as the process gas to model fluid flow. The gas injector received flows of molecular hydrogen gas (10% of the total flow) and molecular oxygen gas (90% of the total flow) contributing to a total gas flow and was kept under isothermal process conditions. The temperature of the process chamber, substrates, and gas was set in the model at 550° C. and radiation-heating effects were ignored. The CFD computation considered the foreline pressure to be fixed at 450 mT and was calculated at different total gas flows ranging from 2,666 standard cubic centimeters per minute (sccm) to 10,666 sccm.

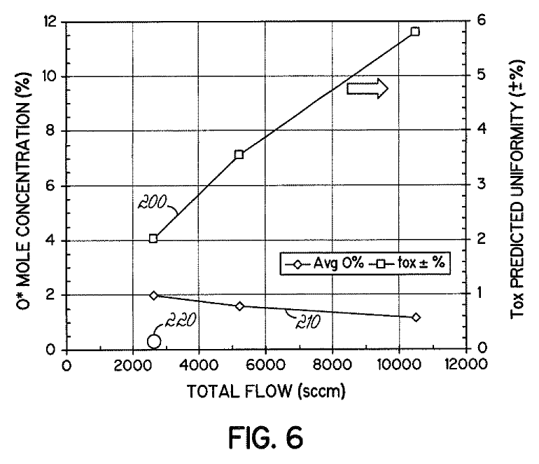

FIG. 6 is a graph representing the mole concentration of atomic oxygen, along the left hand ordinate axis (i.e., the y-axis) of the plane Cartesian coordinate system, and the predicted oxidation uniformity, along the right hand ordinate axis, as a function of the total gas flow plotted along the abscissa (i.e., the x-axis). Line 200 represents the mole concentration of atomic oxygen determined from the CFD computation as a function of the total gas flow. Line 210 represents the predicted oxidation uniformity determined from the CFD computation as a function of the total gas flow. Point 220 represents the mole concentration of atomic oxygen determined from a CFD computation under the same nominal simulation conditions and with a total gas flow of 2,666 sccm for a thermal processing system incorporating a conventional gas injector in which molecular hydrogen gas and molecular oxygen gas are injected at the top of the process chamber. As apparent, the gas injector having sub-chambers as described herein enhances the concentration of atomic oxygen in the process chamber while maintaining an acceptable level of oxidation thickness uniformity. In particular, the simulation results indicated that the concentration of atomic oxygen in the process chamber is significantly enhanced in comparison with the simulation results determined under nominally equivalent simulation conditions in a conventional thermal processing system. For example, the predicted oxidation thickness uniformity at the lowest gas flow is approximately 2 percent and the improvement in the concentration of atomic oxygen was calculated to be on the order of 5 times to 6 times the concentration in a conventional thermal processing system.

The enhancement of the concentration of atomic oxygen in the process chamber, which is simulated in FIG. 6 for a process temperature of 550° C., is expected to be observed at other process temperatures in a range extending from as low as 400° C. up to as high as 1150° C. In this temperature range and in view of the simulated results, conventional thermal processing systems incorporating conventional gas injectors are believed to be unable to match the concentration of atomic oxygen in the process chamber achieved employing a gas injector having sub-chambers as described in the embodiments herein.

While the invention has been illustrated by the description of one or more embodiments thereof, and while the embodiments have been described in considerable detail, they are not intended to restrict or in any way limit the scope of the appended claims to such detail. Additional advantages and modifications will readily appear to those skilled in the art. The invention in its broader aspects is therefore not limited to the specific details, representative apparatus and method and illustrative examples shown and described. Accordingly, departures may be made from such details without departing from the scope of the general inventive concept.

What is claimed is:

1. A thermal processing system for processing substrates, the thermal processing system comprising:
a tubular member defining a process chamber configured to process the substrates; and
a gas injector including a manifold body disposed in the process chamber, the manifold body including a first tubular conduit, a first lumen defined inside the first tubular conduit, a plurality of injection outlets coupling the first lumen in fluid communication with the process chamber, a second lumen that confines a first process gas, and a third lumen that confines a second process gas inside the manifold body and segregated from the first process gas, the second and third lumens coupled in fluid communication with the first lumen, and the first tubular conduit configured to combine the first and second process gases to promote a chemical reaction within the first lumen that produces a reaction product for injection through the injection outlets into the process chamber.

2. The thermal processing system of claim 1 further comprising:
a second tubular conduit enclosing the second lumen, the second tubular conduit including a first plurality of passages configured to transfer the first process gas from the second lumen to the first lumen of the first tubular conduit; and
a third tubular conduit enclosing the third lumen, the third tubular conduit including a second plurality of passages configured to transfer the second process gas from the third lumen to the first lumen of the first tubular conduit.

3. The thermal processing system of claim 2 wherein the injection outlets are substantially aligned in row, and the first plurality of passages and the second plurality of passages are each substantially aligned in respective first and second rows that are oriented substantially parallel with the rows of the injection outlets.

4. The thermal processing system of claim 1 wherein the injection outlets are substantially aligned in row, the substrates are supported with parallelism in a stacked arrangement inside the process chamber such that the injection outlets and the substrates have a substantially identical pitch, and a majority of the injection outlets have a central axis that is aligned with a plane equidistant from a nearest adjacent pair of substrates.

5. The thermal processing system of claim 1 further comprising:
a first mass flow controller outside of the process chamber, the first mass flow controller configured to control a mass flow of the first process gas to the second lumen; and
a second mass flow controller outside of the process chamber, the second mass flow controller configured to control a mass flow of the second process gas to the third lumen.

6. The thermal processing system of claim 1 further comprising:
an outer vessel disposed radially outside of the tubular member, the tubular member and the outer vessel separated by an annular pumping space; and
a longitudinal slit extending through the tubular member to couple said process chamber and said annular pumping space in fluid communication.

7. The thermal processing system of claim 6 wherein the tubular member is substantially centered about an azimuthal axis such that the substrates are disposed radially inside the tubular member, and the longitudinal slit has a length substantially aligned with the azimuthal axis.

8. The thermal processing system of claim 7 wherein the injection outlets in the manifold body are aligned in a row substantially parallel with the azimuthal axis.

9. A method for delivering first and second process gases to a process chamber of a thermal processing system, the method comprising:
combining the first and second process gases within a tubular conduit inside the process chamber to promote a chemical reaction producing a reaction product;
injecting the reaction product into the process chamber from injection outlets coupling the tubular conduit with the process chamber; and
exposing a plurality of substrates supported inside the process chamber to the reaction product.

10. The method of claim 9 further comprising:
delivering the first process gas to the tubular conduit from a location outside of the process chamber; and
delivering the second process gas to the tubular conduit from a location outside of the process chamber without permitting the first and second process gases to chemically react before being combined within the tubular conduit.

11. The method of claim 10 wherein delivering the second process gas to the tubular conduit further comprises:
communicating the first and second process gases from the respective locations outside of the process chamber independently to the tubular conduit in which the first and second process gases combined.

12. The method of claim 10 wherein delivering the second process gas to the tubular conduit further comprises:
delivering the first and second process gases from the respective locations outside of the process chamber through separate tubular conduits to the tubular conduit in which the first and second process gases combined.

13. The method of claim 9 further comprising:
heating the first and second process gases prior to combining inside the tubular conduit; and
heating the tubular conduit to a temperature effective to promote the chemical reaction.

14. The method of claim 9 wherein exposing the stack of substrates to the reaction product further comprises:
forming a layer on at least one surface of each of the substrates.

15. The method of claim 14 wherein forming the layer further comprises:
oxidizing the at least one surface of each of the substrates to define the layer.

16. The method of claim 9 wherein the injection outlets have a linear arrangement, the substrates are arranged in a stack with a gap between each adjacent pair of substrates, and further comprising:
evacuating the process chamber through an longitudinal slit aligned with the injection outlets and separated from the tubular conduit by the stack of substrates to promote a cross flow diametrically across the substrates in the stack.

17. The method of claim 9 wherein the first process gas is an oxidizing gas and the second process gas is a reducing gas, and further comprising:
delivering the oxidizing and reducing gases from respective locations outside of the process chamber to the tubular conduit without promoting the chemical reaction before the oxidizing and reducing gases are combined within the tubular conduit.

18. The method of claim 9 wherein the first process gas is molecular oxygen and the second process gas is molecular hydrogen, and further comprising:
delivering the molecular oxygen and the molecular hydrogen from respective locations outside of the process chamber to the tubular conduit without permitting the molecular oxygen and the molecular hydrogen to chemically react before being combined within the tubular conduit.

19. The method of claim 18 wherein the reaction product is atomic oxygen, and exposing the stack of substrates supported inside the process chamber further comprises:
reacting the atomic oxygen with the substrates to form an oxide layer on at least one surface of each of the substrates.

20. The method of claim 18 wherein delivering the molecular oxygen and the molecular hydrogen to the tubular conduit further comprises:
delivering the molecular oxygen and the molecular hydrogen from respective locations outside of the process chamber through separate tubular conduits at least partially disposed inside the process chamber to the tubular conduit in which the first and second process gases combined.

21. The method of claim 9 further comprising:
evacuating the process chamber concurrently with injecting the reaction product from injection outlets into the process chamber for controlling a sub-atmospheric pressure inside the process chamber.
